(19) United States
(12) Patent Application Publication
(10) Pub. No.: US 2008/0317171 A1
(43) Pub. Date: Dec. 25, 2008

(54) Impulse Calibration Of An IQ Demodulator And Low Frequency DC-Coupled Cross-Over Network

(76) Inventor: Roger Lee Jungerman, Petaluma, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/764,900

(22) Filed: Jun. 19, 2007

(51) Int. Cl. H03K 9/00

(52) U.S. Cl. 375/323

(57) ABSTRACT

A method for calibrating an I Q demodulator includes measuring I, Q, and low frequency data, correcting each set of measured data, combining the corrected I and Q data, interpolating the corrected low frequency data, and combining the corrected low frequency data and the combined corrected I and Q data.

### BACKGROUND

Frequency response calibration of data converters has been used at RF and microwave frequencies. The output of the digitizer for a sinusoidal test stimulus is compared to a microwave power meter, as the frequency of the test stimulus is varied. Unfortunately, the method does not have a phase reference, which is needed for time domain measurements.

Oscilloscopes are sometimes calibrated using an impulse technique. An electrical impulse (produced from a step recovery diode or other technique) is measured on a very high frequency sampling oscilloscope. This sampler is assumed to have perfect response, or it can be calibrated by various electro-optic methods. NIST has a program to produce calibrated traceable measurements of impulses.

With a calibrated impulse system, the ADC (or real-time scope) under test can be measured. The known impulse system response is deconvolved from the measured test impulse on the ADC under test.

In an ADC system using IQ demodulation and a low frequency cross-over network, a more complex calibration approach is required.

### SUMMARY

A method for calibrating an I Q demodulator includes measuring I, Q, and low frequency data, correcting each set of measured data, combining the corrected I and Q data, interpolating the corrected low frequency data, and combining the corrected low frequency data and the combined corrected I and Q data.

### BRIEF DESCRIPTION OF THE DRAWINGS

FIG. 1 illustrates an I Q demodulator of the prior art.

FIG. 2 illustrates an I Q demodulator of the prior art.

FIG. 3 illustrates a block diagram of the present invention.

### DETAILED DESCRIPTION

As the frequency of digital and RF signals continues to increase, there is a need to increase the speed of measurement systems used to observe these waveforms. At the highest rates, equivalent time sampling systems have been employed that can measure signals with very high bandwidth (up into the mm wave frequency range). These sampling measurements have very low sampling frequency and only work for repetitive waveforms. They do not perform a “single-shot” acquisition of the incoming waveform. To capture the full waveform, an A/D converter working at the full bandwidth of the incoming signal with a sample rate of at least two times the highest measured frequency (set by the Nyquist requirement) is needed. This A/D requirement is very stringent and has driven the design of high-speed real-time oscilloscopes. Using an IQ demodulator and low frequency crossover network makes it possible to capture a DC coupled waveform with an AC coupled IQ demodulator and high speed front end amplifier. Reconstructing the actual waveform from the combination of the low frequency and high frequency ADC data, requires a suitable test stimulus and calibration method.

Mixers are commonly used to down convert narrow-band RF signals to a lower frequency IF. These mixers are used in both radio systems as well as in spectrum analyzer measurement equipment. Typically, the dynamic range of the mixer greatly exceeds the dynamic range of a multi-GS/s ADC.

A specialized type of mixer, I Q demodulator, may be used to produce two low frequency quadrature outputs. With proper calibration, it is possible to separately digitize the I Q demodulator outputs to achieve twice the aggregate digitized bandwidth, while each ADC operates at half the aggregate rate.

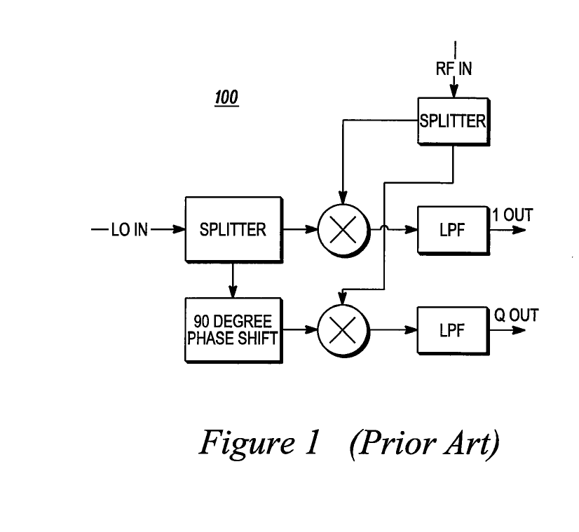

I Q demodulators (shown in FIG. 1) are typically AC coupled on the RF in ports. Using large value AC coupling capacitors, the low frequency cut-off can be pushed down to low frequency values. To illustrate, a 20 GHz I Q demodulator can be designed with a low frequency cut-off of 40 MHz. Alternatively it is possible to design a DC coupled high bandwidth I Q demodulator with considerable complexity and performance trade-offs. To illustrate, GaAs is often used for microwave I Q demodulators. If GaAs is used in a DC coupled device there is significant 1/f noise and DC drift.

To circumvent the problem of a DC coupled IQ demodulator, a low frequency cross-over network can be used. This has the advantage that the low frequency data can be captured in a very accurate, low cost, low bandwidth DC coupled path optimized for this application. Integrated ADCs and DC coupled front-end amplifiers are commonly available. The remaining bandwidth can be captured with the IQ demodulator feeding the high speed ADCs.

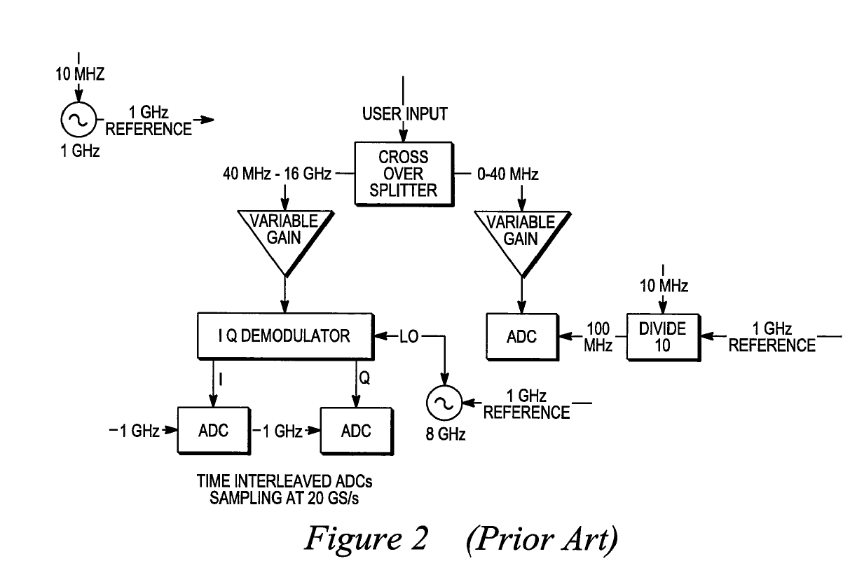

The phase of the local oscillator (LO) into the I Q demodulator must be known relative to the clocks to the ADCs. FIG. 2 illustrates an embodiment where all clocks are at multiples of a low frequency reference. All the other higher frequency clocks are at integer multiples of this reference frequency and phase locked to the low frequency reference. The ADC acquisition is initiated synchronous with the low frequency reference. This approach is functionally equivalent to deriving the higher frequency references by multiplying up the low frequency reference, though it will typically result in improved phase noise performance compared to the multiplied reference.

The actual system response will differ significantly from the idealized model. An impulse calibration can be used to correct for these system impairments. A short subset of all possible real physical system errors is listed below:
a) Poor match between the low frequency and high frequency paths in the cross over network
b) Phase variation in the 90 degree split in the IQ demodulator vs. frequency
c) Complex (amplitude and phase) frequency response variations in the low and high frequency paths.

The system can be calibrated by driving the system with an impulse. To obtain lower noise, the impulse can be repetitive. To simplify the calculation, the pulse repetition rate should be a integer sub-multiple of the 10 MHz reference frequency, e,g, 100 KHz for the example shown in FIG. 2. With a repetitive impulse, the signal can be averaged to reduce the noise.

The impulse is measured with a sampling oscilloscope that is assumed to be perfect. If required, the calibration response of the sampling oscilloscope can be deconvolved at this point. This test stimulus is then applied to the ideal model of the system and the three modeled ADC responses are calculated: i(f), q(f), and lf(f). These are the high frequency I and Q channel modeled responses, as well as the low frequency response. The frequency range and frequency point spacing are different for the lf(f) low frequency channel, than for i(f) and q(f) high frequency channels. All these frequency responses (obtained from an FFT of the impulse response) are complex (amplitude and phase).

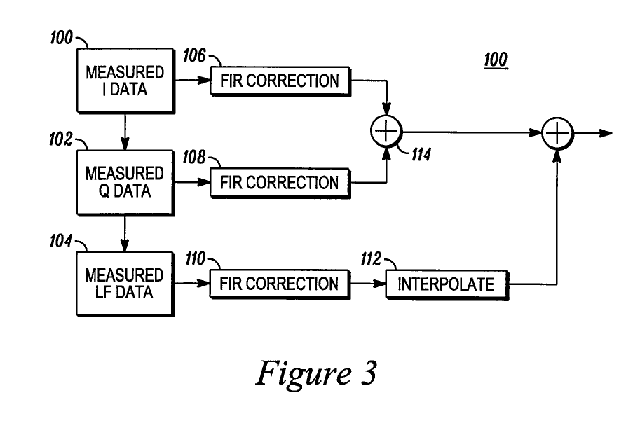

FIG. 3 illustrates an embodiment of measurement correction. In steps 100, 102, and 104, for the I, Q, and low frequency (LF) outputs from the 3 ADCs respectively, the impulse is applied to the actual physical system and the averaged responses are obtained and Fourier transformed. The resulting measured complex frequency responses are: I(f), Q(f), and LF(f).

Next for each response, in steps 106, 108, and 110, a correction factor is obtained by dividing the ideal modeled response by the actual response, e.g. i(f)/I(f). The result is the correction that can be multiplied times the measured frequency response to obtain the ideal frequency response (flat amplitude and phase response and perfect low frequency cross-over). The calculated correction is inverse transformed back to the time domain where it can be applied as a convolution.

The correction is applied to a measured data set. First, the I and Q data are corrected using the separate FIR correction calculated for each. This is performed at the full sample rate (20 GS/s). There are typically sufficiently few points in the high frequency FIR filter (˜20 points) that the frequency spacing of the points (20 GHz/20=1 GHz) is coarse enough that the low frequency cross over is completely missed in this data, with the exception of the DC term (that is assumed to be 0 in the model, since the high frequency path is AC coupled). Next, the low frequency data is corrected at the reduced sample rate of the LF required at full rate, particularly at a reduced sample rate a moderate number of FIR coefficients (˜20 points) can capture the low frequency cross over information (for the illustrated example, frequencies down to 100 MHz/20=5 MHz). The low frequency data is not assumed to be AC coupled, so there is some DC content. Next (step 112), the low frequency data is interpolated up to the full data rate. A CIC interpolator (that requires no multipliers) may be used. To complete the system description that represents the actual data, the correct I and Q data (at full rate) are added together (step 114) and then added to the interpolated LF data (also at full rate) (step 116).

If the LF FIR correction were not applied at a reduced sample rate and then interpolated, an extremely large number of multiplies would be required at the full sample rate. For the example, 20 GHz/5 MHz=4000 points would be required in the FIR filters running at full rate. This would be computationally prohibitive.

The corrections described in FIG. 3 can be performed in several ways in hardware.

In one instance, the corrections can be applied at full rate in the hardware. Two 20 GS/s 20 tap FIR filters would be required together with the interpolator.

In another instance, the corrections can be applied in software using the measured I, Q, and LF data after a batch of data is captured. The LF data can be interleaved with the I and Q captured data without significantly increasing the total number of bits stored. This is due to the reduced sample rate of the LF data. The number of separate corrections required may slow the update rate of the oscilloscope.

In another instance, the data I, Q and LF data can be captured into DRAM memory without corrections. Then, as the data is read out from the memory to the processor to be displayed, it can be corrected in the hardware at a reduced rate. If the data connection is PCI at 500 Mb/s and 8 bits of I data and 8 bits of Q data are sent per sample (the LF data is at a lower rate and doesn't add significantly) then the total PCI throughput rate is 500 MB/s/16 or 31 MSamples/s. A modern FPGA has multipliers that can operate at several hundred MHz. For 20 taps each for the I and Q data (at 31 MS/s) in addition to the LF filter at much reduced rate and the interpolator tens of multipliers would be required. These parts typically have hundreds of multipliers, so “real-time” correction of the data as it is read out of memory seems practical. A dedicated ASIC may be used in place of a FPGA. In this approach, only the final computed result would need to be sent to the processor. This would more than double the data transfer speed as compared to separately sending the I, Q, and LF data to the processor for software correction. In addition, performing the corrections in software will reduce the processor and measurement throughput.

The approach can be extended to cascaded demodulator stages to give even larger sample rates and bandwidths.

A step response may be used rather than an impulse. The step response is essentially the integral of the impulse response.

LO feedthrough drift in the IQ demodulator can be calibrated by simply nulling the input and observing how the DC level of the high speed ADCs has varied from the calibration condition. If the high speed ADC is AC coupled (typically the case with a cross-over network), then the DC level out of the I Q demodulator can be measured with a separate DC voltage sensor on each of the demodulator outputs. This offset measurement is made with the input nulled and is only made occasionally to compensate for temperature drifts in the I Q demodulator. Alternatively, by measuring the temperature of the IQ demodulator, temperature compensation can be used to eliminate any LO feedthrough drift, without the need of a nulling calibration. Since most oscilloscope measurements require only ˜48 dBc spurious performance, it may not be so critical to tract the LO feedthrough drift of the IQ demodulator. These drifts are more critical for LO feedthrough levels below ˜60 dBc.

I claim:

1. A method for calibrating an I Q demodulator comprising:
measuring I, Q, and low frequency data;
correcting each set of measured data;
combining the corrected I and Q data;
interpolating the corrected low frequency data; and
combining the corrected low frequency data and the combined corrected I and Q data.

2. A method for calibrating an IQ demodulator, correcting each set of measured data comprising calculating a step response correction for each set of data.

3. A method for calibrating an IQ demodulator, correcting each set of measured data comprising calculating a finite impulse response correction for each set of data.

4. A method for calibrating an I Q demodulator, as in claim 3, comprising finite impulse response filters implementing calculating a finite impulse response correction.

5. A method for calibrating an IQ demodulator, as in claim 3, comprising a microprocessor implementing calculating a finite impulse response correction.
